(19) United States
(12) Patent Application Publication
(10) Pub. No.: US 2010/0297829 A1
(43) Pub. Date: Nov. 25, 2010

(54) Method of Temporarily Attaching a Rigid Carrier to a Substrate

(75) Inventor: Shawn O'Rourke, Tempe, AZ (US)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: The Arizona Board of Regents, a body corporate acting for and on behalf of Arizona State Unversit, Scottsdale, AZ (US)

(21) Appl. No.: 12/305,737

(22) PCT Filed: Jul. 3, 2007
(86) PCT No.: PCT/US07/72737

§ 371 Date: May 20, 2010

Related U.S. Application Data
(60) Provisional application No. 60/818,631, filed on Jul. 5, 2006.

(51) Int. Cl. H01L 21/50

(52) U.S. Cl. 438/459; 257/E21.499

(57) ABSTRACT

Method for temporarily attaching a substrates to a rigid carrier is described which includes forming a sacrificial layer of a thermally-decomposable polymer, e.g., poly(alkylene carbonate), and bonding the flexible substrate to the rigid carrier with the sacrificial layer positioned therebetween. Electronic components and/or circuits may then be fabricated or other semiconductor processing steps employed (e.g., backgrinding) on the attached substrate. Once fabrication is completed, the substrate may be detached from the rigid carrier by heating the assembly to decompose the sacrificial layer.

### CROSS-REFERENCE TO RELATED APPLICATIONS

This application claims the benefit under 35 U.S.C. §119(e) of U.S. Provisional Application No. 60/818,631, filed Jul. 5, 2006, which is hereby incorporated by reference in its entirety.

### STATEMENT OF GOVERNMENT INTEREST

This work was supported at least in part by U.S. Army Research Labs (ARL) Grant No. W911NF-04-2-005. The U.S. Government has certain rights in the invention.

### FIELD OF THE INVENTION

This invention generally relates to processing flexible substrates and more specifically to a method of temporarily attaching a rigid carrier to a flexible substrate for further processing.

### BACKGROUND OF THE INVENTION

In the electronics industry, thinner and/or more flexible substrates are quickly becoming popular as a base for electronic circuits. Flexible substrates can include a wide variety of materials including very thin layers of metal, such as stainless steel, any of a myriad of plastics, etc. Once a desired electronic component, circuit, or circuits are formed on a surface of the flexible substrate, the circuit can be attached to a final product or incorporated into a further structure. Typical examples of such products or structures are active matrices on flat panel displays, RFID tags on various commercial products in retail stores, a variety of sensors, etc.

One major problem that arises is stabilizing the thinner and/or more flexible substrates during processing. For example, in a process of fabricating thin film transistors or thin film transistor circuits on a substrate, a large number of process steps are performed during which the substrate may be moved through several machines, ovens, cleaning steps, etc. To move a flexible substrate through such a process, the flexible substrate must be temporarily mounted in some type of carrier or a rigid carrier must be removably attached, so that the flexible carrier can be moved between process steps without flexing and the carrier can be removed when the process steps are completed. Alternatively, thinned substrates produced by backgrinding of a thicker semiconductor substrate need to be supported during the backside grinding process and throughout the subsequent processes such as lithography, deposition, etc.

### SUMMARY OF THE INVENTION

In a first aspect, the invention provides methods for fabricating electronic components and/or circuits on a flexible substrate, comprising, temporarily attaching a flexible substrate to a rigid carrier; and fabricating electronic components and/or circuits on an exposed surface of the flexible substrate.

In a second aspect, the invention provides methods for fabricating electronic components and/or circuits on a semiconductor substrate, comprising temporarily attaching a semiconductor substrate comprising a first face, second face, and a thickness, wherein the first face comprises at least one electronic component and/or circuit; to a rigid carrier with a fugitive material film, wherein the fugitive material film is between the first face of the semiconductor substrate and the rigid carrier; and the fugitive material comprises a poly(alkylene carbonate).

### BRIEF DESCRIPTION OF THE DRAWINGS

FIG. 1 is a simplified sectional view illustrating an initial procedure in a method of temporarily attaching a rigid carrier to a flexible substrate in accordance with the present invention;

FIG. 2 is a simplified sectional view illustrating further procedures for temporarily attaching a rigid carrier to a flexible substrate;

FIG. 3 is a simplified sectional view illustrating another method of temporarily attaching a rigid carrier to a flexible substrate in accordance with the present invention; and

FIG. 4 illustrates a diagram for the chemical reaction during pyrolysis or combustion of the decomposition of a fugitive material layer in accordance with the present invention.

### DEFINITIONS

The term “fugitive material” as used herein means a thermally decomposable material. Such materials decompose into smaller and/or more volatile molecules upon heating above a critical decomposition temperature, as defined herein. Non-limiting examples of thermally decomposable materials include poly(alkylene carbonate)s, nitrocellulose, ethylcellulose, poly(methyl methacrylate) (PMMA), poly(vinyl alcohol), poly(vinyl butyryl), poly(isobutylene), poly(vinyl pyrrolidone), microcrystalline celluloses, waxes, poly(lactic acid), poly(dioxanone)s, poly(hydroxybutyrate)s, poly(acrylate)s, and poly(benzocyclobutene)s.

The term “preformed flexible substrate” as used herein means that the flexible substrate, as defined herein, is a free-standing substrate prior to bonding with the rigid carrier.

The term “double-sided adhesive tape” as used herein means any tape comprising a supporting backing with an adhesive material on each of the two opposing faces thereof. The adhesives on opposing faces may be the same or different, and include, for example but not limited to elastomeric, thermoplastic, thermosetting, pressure-sensitive, and/or light-curable adhesives (e.g., visible or UV).

The term “flexible substrate” as used herein means a free-standing substrate comprising a flexible material which readily adapts its shape. Non-limiting examples of flexible substrates include, but are not limited to films of metals and polymers, e.g. metal foils, such as aluminum and stainless steel foils, and polymeric sheets, such as polyimides, polyethylene, polycarbonates, polyethylene terephthalate (PET), polyethylene naphthalate (PEN), polyethersulfone (PES), and multi-layer stacks comprising two or more metal and/or polymeric materials provided the entire stack assembly remains flexible. Such substrates are preferably thin, e.g. less than 2 mm thick, and preferably less than 1 mm thick; even more preferably, the substrate is less than 500 μm thick, and preferably about 50-200 μm thick.

The term “softened state” as used herein means that the material is at a temperature greater than its glass-transition temperature, but less than its decomposition temperature, as defined herein.

The term “decomposition temperature” means the temperature at which a composition comprising at least one thermally decomposable material begins to decompose into smaller and/or more volatile molecules.

The term “alkylene” as used herein means a linear or branched diradical hydrocarbon consisting of 2 to 10 carbon atoms. Examples of alkylenes include, but are not limited to, ethylene, butylene, hexamethylene, and the like.

The term “flat” as used herein means that each point on the surface is less than about 100 μm from a line defined by the center of the substrate; preferably, each point on the surface is less than about 75 μm from a line defined by the center of the substrate; even more preferably, each point on the surface is less than about 60 μm from a line defined by the center of the substrate.

### DETAILED DESCRIPTION OF THE INVENTION

In the first aspect, the invention provides methods for fabricating electronic components and/or circuits on a flexible substrate, comprising temporarily bonding a flexible substrate to a rigid carrier according and fabricating electronic components and/or circuits on an exposed surface of the substrate.

In one embodiment of the first aspect, the invention provides the method wherein temporarily attaching a flexible substrate to a rigid carrier comprises forming a film comprising a fugitive material on the rigid carrier or the flexible substrate; and bonding the flexible substrate to the rigid carrier with the film positioned between the flexible substrate and the rigid carrier.

In preferred embodiments of the first aspect, the invention provides the method wherein forming the film of the fugitive material on the rigid support or flexible substrate comprises forming a layer of a solution comprising the fugitive material in a solvent on the rigid carrier or the flexible substrate; and drying the layer to form the film.

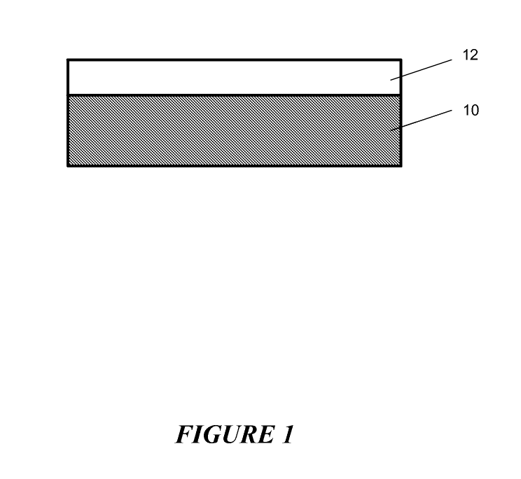

In one embodiment, as illustrated in FIG. 1, the rigid carrier 10 is coated with a film of the fugitive material 12 of the invention. The solution of the fugitive material comprises the fugitive material, such as a poly(alkylene carbonate), dissolved in an appropriate solvent. The fugitive material and solvent (or solvents) are batched and allowed to dissolve while rolling or otherwise agitating (or mixing) for an extended period of time. Heat may be applied to dissolve the fugitive material provided the temperature is kept below the critical decomposition temperature of the fugitive material. The solution of the fugitive material may further comprise additives, such as nitrocellulose or ethylcellulose, to adjust the decomposition temperature of the fugitive material film (infra).

The film of the fugitive material on the rigid carrier or flexible substrate using a solution of the fugitive material may be prepared according to any method known to those skilled in the art for preparing a film from a solution. For example, the solution may be spray coated, drop cast, spin coated, webcoated, doctor bladed, or dip coated to produce a layer of the solution on the carrier or substrate. When the layer is formed on the rigid carrier, preferably, the solution is spin coated by dispensing the solution on a surface of the rigid carrier and spinning the carrier to evenly distribute the solution. One skilled in the art will understand that the thickness of the layer, and ultimately the film, produced by spin coating may be controlled by selection of the concentration of the fugitive material in the solvent, the viscosity of the solution, the spinning rate, and the spinning speed.

The solution layer may be dried prior to bonding of the flexible substrate or rigid carrier to essentially remove any remaining solvent and produce the fugitive material film. This drying may be according to any method known to those skilled in the art provided the method does not cause deterioration of the substrate, carrier, and/or fugitive material. For example, the layer may be dried by heating the layer at a temperature in the range of approximately 80° C. to 180° C., and preferably, about 100° C. to 130° C. In another example, the layer may be dried by heating the layer in a vacuum a temperature in the range of approximately 100° C. to 180° C. In yet another example, the layer may be dried by heating the layer at a temperature in the range of approximately 80° C. to 180° C., followed by heating the layer in a vacuum (e.g., less than about 1 torr) at temperature in the range of approximately 100° C. to 180° C. In either heating process, the layer may be heated for about 10 to 120 minutes until substantially all the solvent is removed. One skilled in the art will recognize that higher temperatures (e.g., up to 300° C.) may be used in any of the heating steps provided the fugitive material remains stable during heating.

Ultimately, it is preferred that the fugitive material film 12 is between 1 μm and 40 μm thick, and more preferably between 2 μm and 20 μm thick.

Alternatively, the layer of the fugitive material solution may be coated onto the back side of flexible substrate 14, followed by a drying and/or vacuum drying process, as discussed previously, to produce a fugitive material film 12 on a flexible substrate 14. Preferably, when the film of the fugitive material is formed on the flexible substrate, the layer of the solution is produced by spin coating of the solution followed by drying of the layer to produce the film, as discussed previously.

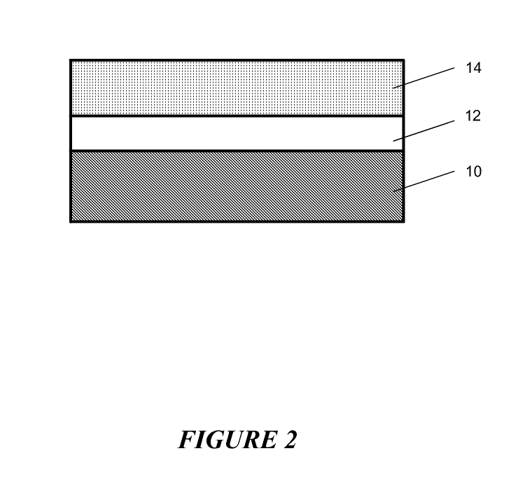

As illustrated in FIG. 2, in the instant method of the invention, the free-standing flexible substrate 14 bonded to the upper surface of fugitive material film 12. Several different procedures can be used bond the flexible substrate 14 on fugitive material film 12.

In one embodiment, bonding the flexible substrate comprises heating the fugitive material film (either on the flexible substrate or the rigid carrier) to a softened state, i.e. above the glass transition temperature (T_{g}) of the fugitive material, and attaching the substrate directly to the carrier. The specific softening temperature for use in the present invention can be determined empirically based on the teachings herein, and depends upon the specific material used in fugitive material film 12. For example, T_{g} may be determined using techniques such as, but not limited to, thermogravimetric analysis (TGA), thermomechanical analysis (TMA), differential scanning calorimetry (DSC), and/or dynamic mechanical analysis (DMA). Thus, in this embodiment fugitive material film 12 acts as an adhesive material as well as the fugitive material.

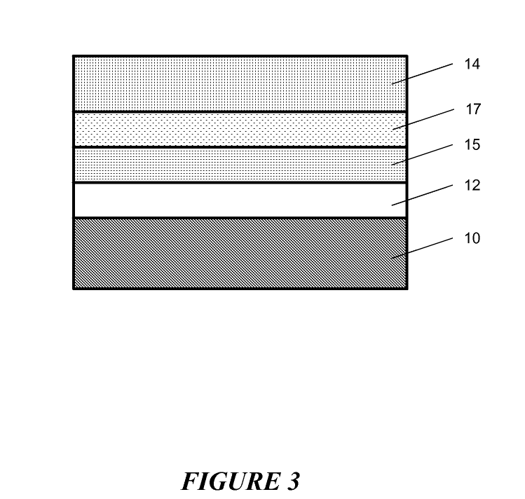

In another embodiment, as illustrated in FIG. 3, bonding the flexible substrate comprises depositing a layer of a metal or insulating layer 15 on the fugitive material film on the rigid carrier; positioning a double-sided adhesive 17 on layer 15; and positioning the substrate 14 on the double-sided adhesive. Preferred metals include, but are not limited to, metals which may be deposited by sputtering, for example, aluminum, gold, and silver. Preferred insulating layers include those which may be deposited by plasma enhanced chemical vapor deposition (PECVD), such as, SiN and SiO₂. Preferred double sided adhesives include, but are not limited to, double sided powder coated silicone adhesives (Argon PC500 family), or high performance silicone adhesives (Adhesive Research Arcare 7876) or similar.

With flexible substrate 14 temporarily attached to rigid carrier 10, all of the desired processing steps can be performed on flexible substrate 14 to fabricate electronic circuits. As the final system, prepared according to the first aspect, may be approximately the same size as a semiconductor wafer, standard processing tools may be used to perform the fabrication. Once the desired electronic fabrication or processing steps are completed, removal of the fugitive material film affects detachment of the flexible substrate from the rigid carrier.

In a further embodiment of the first aspect, the invention provides the method wherein after fabrication, the flexible substrate is detached from the rigid carrier; preferably, the flexible substrate is detached by heating the fugitive material film. Preferably, the fugitive material is heated to and maintained at a temperature where the fugitive material film decomposes. Such heating is preferably performed in air or an inert atmosphere (e.g. nitrogen). More preferably, such heating is performed in air.

Decomposition temperatures and duration of heating for the fugitive materials and films thereof of the instant invention can be readily determined utilizing methods known to those skilled in the art based on the teachings herein, for example, using thermogravimetric analysis (TGA). As noted previously, other materials can be used in fugitive material film 12 to adjust the decomposition temperature. That is, the temperature at which the fugitive material film is removed may be raised or lowered as necessary as required to maintain the stability of by the material of the flexible substrate and/or compatibility with various electronic processing steps and materials.

Other processes may be used to affect removal of the fugitive material film. For example, a flash lamp, an RTA (Rapid Thermal Anneal) process using a halogen lamp, or a laser, may be used to combust fugitive material film 12.

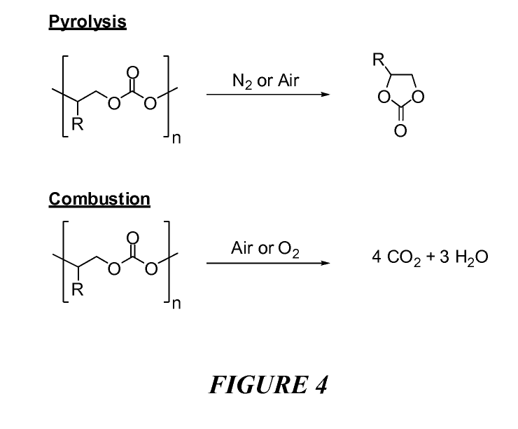

When poly(alkylene carbonate)s are utilized in the fugitive material film 12, preferably poly(propylene carbonate), such materials exhibit an ultra-clean and rapid decomposition in air or inert atmosphere as illustrated in the diagrams of FIG. 4. The decomposition can be either pyrolysis or combustion. For example, when poly(alkylene carbonate)s are utilized in the fugitive material film 12, and especially poly(propylene carbonate), the fugitive material film may removed at a temperature of at least 240° C., and preferably, between 240° C. and 300° C.; more preferably, between 240° C. and 260° C.

In each of the preceding embodiments, the fugitive material film comprises, preferably, a thermally decomposable polymer. More preferably, the fugitive material film comprises at least one material selected from a group consisting of poly(alkylene carbonate)s, nitrocellulose, ethylcellulose, poly(methyl methacrylate), poly(vinyl alcohol), poly(vinyl butyryl), poly(isobutylene), poly(vinyl pyrrolidone), microcrystalline celluloses, waxes, poly(lactic acid), poly(dioxanone), poly(hydroxybutyrate), poly(acrylate)s, poly(benzocyclobutene)s, and mixtures thereof. Even more preferably, the fugitive material film comprises a poly(alkylene carbonate)s, for example, poly(ethylene carbonate) [QPAC®25], poly(propylene carbonate) [QPAC®40], poly(butylene carbonate) or mixtures thereof. Even more preferably, the fugitive material film comprises poly(propylene carbonate). As poly(alkylene carbonate)s have an ultra-clean decompositions, such materials are advantageous in the instant invention for their low risk of contaminating semiconductor devices.

In each of the preceding embodiments, the flexible substrate preferably is a preformed flexible substrate. More preferably, the flexible substrate is a preformed flexible plastic substrate or a preformed flexible metal substrate. Preferred flexible metal substrates include FeNi alloys (e.g., INVAR™, FeNi, or FeNi36; INVAR™ is an alloy of iron (64%) and nickel (36%) (by weight) with some carbon and chromium), FeNiCo alloys (e.g., KOVAR™, KOVAR™ is typically composed of 29% nickel, 17% cobalt, 0.2% silicon, 0.3% manganese, and 53.5% iron (by weight)), titanium, tantalum, molybdenum, aluchrome, aluminum, and stainless steel. Preferred flexible plastic substrates include polyethylene naphthalate (PEN), polyethylene terephthalate (PET), polyethersulfone (PES), polyimide, polycarbonate, and cyclic olefin copolymer. Such flexible substrates are preferably thin; preferably, about 1 μm to 1 mm thick. More preferably, the flexible substrate is about 50 μm to 500 μm; even more preferably, about 50 μm to 250 μm.

In each of the preceding embodiments, the rigid carrier comprises any material that is capable of withstanding the processing used to fabricate electronic components or circuits. Preferably, the rigid carrier comprises a semiconducting material. In other preferred aspects and embodiments, the rigid carrier preferably has at least one substantially flat surface. More preferably, the rigid carrier is a semiconductor wafer. Even more preferably, the rigid carrier is a silicon wafer (preferably, with a flat surface).

In a second aspect, the invention provides methods for fabricating electronic components and/or circuits on a semiconductor substrate, comprising
temporarily attaching a semiconductor substrate comprising a first face, second face, and a thickness, wherein
   the first face comprises at least one electronic component and/or circuit;
to a rigid carrier with a fugitive material film, wherein
   the fugitive material film is between the first face of the semiconductor substrate and the rigid carrier; and
   the fugitive material comprises a poly(alkylene carbonate).

In an embodiment of the second aspect, the method further comprises backgrinding the second face of the semiconductor substrate to decrease the thickness of the semiconductor substrate. Preferably, backgrinding comprises mechanical grinding and/or wet etching.

In another embodiment of the second aspect, the method further comprises backgrinding the second face of the semiconductor substrate to decrease the thickness of the semiconductor substrate; and heating the fugitive layer to detach the semiconductor substrate from the rigid carrier. The fugitive layer is preferably heated according to any of the conditions discussed with respect to the first aspect of the invention.

In any of the embodiments of the second aspect, the fugitive material placed on either the first face of the semiconductor substrate or the rigid carrier and may be produced according to any of the method discussed previously with respect to the first aspect of the invention.

Further, in any of the embodiments of the second aspect, the rigid carrier may comprise a semiconductor substrate or glass; preferably, the rigid carrier comprises Si or Si(100). Any semiconductor substrate utilized in the method of the second aspect may independently comprise Si, SiGe, Ge, SiGeSn, GeSn, GaAs, InP, and the like. Preferably, any semiconductor substrate utilized in the method may independently comprise Si or Si(100). The fugitive material preferably comprises poly(propylene carbonate) or poly(ethylene carbonate), and more preferably, the fugitive material is poly(propylene carbonate). The fugitive material film may comprise additives, such as nitrocellulose or ethylcellulose, to adjust the decomposition temperature of the fugitive material film (supra).

The poly(alkylene carbonate)s utilized in the fugitive material film exhibit ultra-clean and rapid decomposition in air or inert atmosphere. Particularly advantageous is the clean and raid decomposition of the poly(alkylene carbonate) fugitive materials. Further, fugitive material films may removed at a temperature of at least 240° C., and preferably, between 240° C. and 300° C.; more preferably, between 240° C. and 260° C. The decomposition at less than 300° C. and clean and rapid decomposition of the fugitive material in an air atmosphere provided unexpected advantages in the handling and fabrication of semiconductor devices.

### EXAMPLES

### Example 1

### Preparation of a Film of Poly(Propylene Carbonate) on a Rigid Carrier

72 g of poly(propylene carbonate) (QPAC® 40) was mixed into 150 g of ethyl acetate and 528 g of diethylene glycol monoethyl ether acetate (Eastman DE Acetate). The materials were batched and allowed to dissolve for 24 hours while rolling gently. After preparation of the solution, 20 mL was dispensed on the upper surface of a silicon wafer and spun at 400 rpm for 20 seconds. The spun-on material was then dried at 120° C. for 40 minutes to form a film of the poly(propylene carbonate) on the upper surface of silicon wafer. To ensure the substantially complete removal of the solvent from the poly(propylene carbonate) film, the system was vacuum baked at 100° C. for 16 hours and then vacuum baked a final hour at 180° C.

### Example 2

### Assembly of a Flexible Stainless Steel Substrate on a Rigid Carrier

A film of poly(propylene carbonate) on a silicon wafer rigid support was prepared according to Example 1. A flexible stainless steel substrate was positioned on the surface of the poly(propylene carbonate) film so as to be aligned with silicon wafer. The assembly was then heated until the poly(propylene carbonate) layer was slightly softened, approximately 120° C. to 140° C., to affect temporary bonding between the stainless steel substrate and rigid carrier.

### Example 3

### Alternative Assembly of a Flexible Stainless Steel Substrate on a Rigid Carrier

A film of poly(propylene carbonate) on a silicon wafer rigid support was prepared according to Example 1. A layer of aluminum (approximately 5000 Å thick) was sputtered onto the surface of the poly(propylene carbonate) film. Next, a double-sided adhesive layer was positioned on the upper surface of aluminum layer and a stainless steel foil (Sumitomo, type 304; 125 μm thick) was positioned on the upper side of double-sided adhesive layer.

Various changes and modifications to the methods and embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

We claim:

1. A method for fabricating electronic components and/or circuits on a flexible substrate, comprising,
temporarily attaching a flexible substrate to a rigid carrier; and
fabricating electronic components and/or circuits on an exposed surface of the flexible substrate.

2. The method of claim 1, wherein temporarily attaching a flexible substrate to a rigid carrier comprises
forming a film comprising a fugitive material on the rigid carrier or the flexible substrate;
bonding the flexible substrate to the rigid carrier with the film positioned between the flexible substrate and the rigid carrier.

3. The method of claim 2, wherein forming a film comprising a fugitive material comprises
forming a layer of a solution comprising a fugitive material in a solvent on the rigid carrier or flexible substrate; and
drying the solution layer to form the film.

4. The method of claim 2, wherein the fugitive material is a thermally decomposable polymer.

5. The method of claim 4, wherein the fugitive material is selected from a group consisting of a poly(alkylene carbonate), nitrocellulose, ethylcellulose, poly(methyl methacrylate), poly(vinyl alcohol), poly(vinyl butyryl), poly(isobutylene), poly(vinyl pyrrolidone), microcrystalline cellulose, waxes, poly(lactic acid), poly(dioxanone), poly(hydroxybutyrate), poly(acrylate), poly(benzocyclobutene), and mixtures thereof.

6. The method of claim 5, wherein the fugitive material is a poly(alkylene carbonate) or mixture thereof.

7. The method of claim 6, wherein the fugitive material is a poly(propylene carbonate).

8. The method of claim 2, wherein the flexible substrate is a plastic substrate or a metal substrate.

9. The method of claim 8, wherein the plastic substrate comprises polyethylene naphthalate (PEN), polyethylene terephthalate (PET), polyethersulfone (PES), polyimide, polycarbonate, cyclic olefin copolymer or mixtures thereof.

10. The method of claim 8, wherein the metal substrate comprises INVAR, KOVAR, titanium, tantalum, molybdenum, aluchrome, aluminum, and stainless steel.

11. The method of claim 2, wherein the rigid carrier is a semiconductor wafer.

12. The method of claim 3, wherein forming a layer of a fugitive material in a solvent on the rigid carrier comprises
dispensing the solution on a surface of the rigid carrier; and
spinning the carrier to evenly distribute the solution.

13. The method of claim 3, wherein drying the layer of the solution comprises drying at a temperature in the range of approximately 80° C. to 180° C.

14. The method of claim 13, wherein drying the layer of the solution further comprises vacuum baking at a temperature in the range of approximately 100° C. to 180° C.

15. The method of claim 2, wherein bonding the flexible substrate to the rigid carrier comprises
heating the layer of fugitive material to a softened state; and
attaching the flexible substrate directly to the rigid carrier.

16. The method of claim 3, wherein the solution further comprises nitrocellulose or ethylcellulose.

17. The method of claim 2, wherein bonding the flexible substrate to the rigid carrier comprises
depositing a metal layer or insulating layer on the film;
positioning a double-sided adhesive on the aluminum layer; and
positioning the flexible substrate on the double-sided adhesive.

18. The method of claim 15, wherein the metal layer comprises aluminum.

19. The method of claim 15, wherein the insulating layer comprises SiN or SiO₂.

20. The method of claim 1, further comprising,
detaching the flexible substrate from the rigid carrier after fabrication.

21. The method of claim 20, wherein detaching the substrate comprises
heating the fugitive material to a temperature greater than or equal to the decomposition temperature of the fugitive material.

22. The method of claim 21, wherein the fugitive material is heated to a temperature between about 240° C. to 300° C.

23. The method of claim 21, wherein the fugitive material is heated in air.

24. A method for fabricating electronic components and/or circuits on a semiconductor substrate, comprising
temporarily attaching a semiconductor substrate comprising
a first face, a second face and a thickness, wherein the first face comprises at least one electronic component and/or circuit;
to a rigid carrier with a fugitive material film, wherein
the fugitive material film is between the first face of the semiconductor substrate and the rigid carrier; and
the fugitive material comprises a poly(alkylene carbonate).

25. The method of claim 24, further comprising,
backgrinding the second face of the semiconductor substrate to decrease the thickness of the semiconductor substrate.

26. The method of claim 25, wherein backgrinding comprises mechanical grinding or wet etching.

27. The method of claim 25, further comprising,
heating the fugitive layer to detach the semiconductor substrate from the rigid carrier.

28. The method of claim 27, wherein the fugitive material is heated to a temperature between about 240° C. to 300° C.

29. The method of claim 27, wherein the fugitive material is heated in the presence of air.

30. The method of claim 24, wherein temporarily attaching a semiconductor substrate to a rigid carrier comprises
forming a film comprising the fugitive material on the rigid carrier or the semiconductor substrate; and
bonding the semiconductor substrate to the rigid carrier with the film positioned between the flexible substrate and the rigid carrier.

31. The method of claim 30, wherein forming a film comprising a fugitive material comprises
forming a layer of a solution comprising the fugitive material in a solvent on the rigid carrier or semiconductor substrate; and
drying the solution layer to form the film

32. The method of claim 24, wherein the poly(alkylene carbonate) is poly(propylene carbonate) or poly(ethylene carbonate).

33. The method of claim 24, wherein the poly(alkylene carbonate) is poly(propylene carbonate).

34. The method of claim 24, wherein the rigid carrier is a semiconductor substrate or glass.
